(19) United States
(12) Patent Application Publication
(10) Pub. No.: US 2025/0228068 A1
(43) Pub. Date: Jul. 10, 2025

(54) LIGHT-EMITTING ELEMENT, DISPLAY DEVICE, AND METHOD OF MANUFACTURING THE LIGHT-EMITTING ELEMENT

(71) Applicant: Samsung Display Co., Ltd., Yongin-si (KR)

(72) Inventors: SEOULKI LEE, Yongin-si (KR); HWI KIM, Yongin-si (KR); JUNGSUN PARK, Yongin-si (KR); JI-HEE SON, Yongin-si (KR); SEUNGJUN LEE, Yongin-si (KR); AREUM LEE, Yongin-si (KR); YEONHWA LEE, Yongin-si (KR); JOONGU LEE, Yongin-si (KR)

(73) Assignee: Samsung Display Co., Ltd., Yongin-si (KR)

(21) Appl. No.: 18/946,382

(22) Filed: Nov. 13, 2024

(30) Foreign Application Priority Data
Jan. 8, 2024 (KR) 10-2024-0002916

(51) Int. Cl. H10K 50/16; H10K 50/17; H10K 59/30; H10K 59/80; H10K 71/10; H10K 85/60

(52) U.S. Cl. CPC H10K 50/166; H10K 50/171; H10K 59/30; H10K 59/8052; H10K 71/10; H10K 85/626; H10K 85/655; H10K 59/8051

(57) ABSTRACT

A light-emitting element includes a first electrode, a hole transport region, an emission layer, an electron transport region, and a second electrode stacked sequentially. The electron transport region includes an electron transport layer and an electron injection layer, the electron transport layer includes a first electron transport layer and a second electron transport layer on the first electron transport layer, the second electrode includes a second-first electrode on the second electron transport layer, and a second-second electrode adjacent to the second-first electrode in a plan view, the second-first electrode includes a first metal, the second-second electrode includes the first metal and a second metal, and a surface energy of a material included in the second electron transport layer is lower than a surface energy of the first metal, and higher than a surface energy of the second metal.

### CROSS-REFERENCE TO RELATED APPLICATIONS

This application claims priority to and benefits of Korean Patent Application No. 10-2024-0002916 under 35 U.S.C. § 119, filed on Jan. 8, 2024, in the Korean Intellectual Property Office (KIPO), the entire contents of which are incorporated herein by reference.

### BACKGROUND

### 1. Technical Field

The disclosure relates to a light-emitting element having improved light absorption rate, a display device including the light-emitting element which has improved light absorption rate, and a method of manufacturing the light-emitting element with improved process difficulty.

### 2. Description of the Related Art

Various display devices used in multimedia apparatuses such as televisions, mobile phones, tablets, navigation units, and game consoles are being developed. Recently, transparent display devices with a transparent transmissive region in display regions have been developed thanks to advances in technology. In typical transparent display devices, pixel regions and transmissive regions do not overlap in a plan view. However, development is underway for transparent displays that have improved resolution and transparency by overlapping the pixel regions and transparent regions in a plan view.

In order to improve a light absorption rate of the transparent display device, research on methods in which electrodes include materials having a low light absorption rate has been conducted, and a metal self patterning (MSP) method has been used to form a second electrode.

### SUMMARY

The disclosure provides a light-emitting element having improved light absorption rate by facilitating the formation of a region with a low light absorption rate using surface energy difference during the manufacturing processes.

The disclosure also provides a display device including the light-emitting element having improved light absorption rate.

The disclosure also provides a method of manufacturing a light-emitting element with mitigated manufacturing difficulty by facilitating the formation of a region with a low light absorption rate using surface energy difference.

According to an embodiment of the disclosure, a light-emitting element may include a first electrode, a hole transport region disposed on the first electrode, an emission layer disposed on the hole transport region, an electron transport region disposed on the emission layer, and a second electrode disposed on the electron transport region. The electron transport region may include an electron transport layer and an electron injection layer, the electron transport layer may include a first electron transport layer and a second electron transport layer disposed on the first electron transport layer, the second electrode may include a second-first electrode disposed on the second electron transport layer, and a second-second electrode adjacent to the second-first electrode in a plan view, the second-first electrode may include a first metal, and the second-second electrode may include the first metal and a second metal, and a surface energy of a material included in the second electron transport layer may be lower than a surface energy of the first metal and higher than a surface energy of the second metal.

In an embodiment, the first metal may include Ag, and the second metal may include Mg.

In an embodiment, the surface energy of the first metal may be higher than the surface energy of the second metal.

In an embodiment, the surface energy of the material included in the second electron transport layer may be in a range of about 0.642 J/m² to about 0.2 J/m².

In an embodiment, the electron injection layer may include a first electron injection layer disposed on the second electron transport layer, and a second electron injection layer disposed on the first electron transport layer and not overlapping the second electron transport layer in a plan view.

In an embodiment, the first electron injection layer and the second electron injection layer may be integral with each other.

In an embodiment, the first electron injection layer may be directly disposed on the second electron transport layer.

In an embodiment, the second-first electrode may be directly disposed on the first electron injection layer, and the second-second electrode may be directly disposed on the second electron injection layer.

In an embodiment, the first electron injection layer may have a thickness smaller than a thickness of the second electron injection layer.

In an embodiment, an area of the second electron transport layer and an area of the second-first electrode may be substantially same in a plan view.

In an embodiment, an area of the second electron transport layer in a plan view may be smaller than an area of the first electron transport layer in a plan view.

In an embodiment, the material included in the second electron transport layer may include at least one of 9-(2,3,4,5,6-pentadeuteriophenyl)-10-(4-naphthalen-1-ylphenyl)anthracene and 5,5′″-perfluorohexyl-2,2′:5′,2″:5″,2′″-quaterthiophene.

In an embodiment, the hole transport region may include a hole injection layer disposed on the first electrode and a hole transport layer disposed on the hole injection layer.

In an embodiment of the disclosure, a display device may include a circuit layer disposed on a base layer, and a display element layer disposed on the circuit layer and including a light-emitting element. The light-emitting element may include a first electrode, a hole transport region disposed on the first electrode, an emission layer disposed on the hole transport region, an electron transport region disposed on the emission layer, and a second electrode disposed on the electron transport region. The electron transport region may include an electron transport layer and an electron injection layer, the electron transport layer may include a first electron transport layer and a second electron transport layer disposed on the first electron transport layer, the second electrode may include a second-first electrode disposed on the second electron transport layer and a second-second electrode adjacent to the second-first electrode in a plan view, the second-first electrode may include a first metal, and the second-second electrode may include the first metal and a second metal, and a surface energy of a material included in the second electron transport layer may be lower than a surface energy of the first metal and is higher than a surface energy of the second metal.

In an embodiment, the light-emitting element may include a first light-emitting element that emits first light, a second light-emitting element that emits second light, and a third light-emitting element that emits third light. Wavelengths of the first light, the second light, and the third light may be different from each other.

In an embodiment of the disclosure, a method of manufacturing a light-emitting element may include forming a second electron transport layer on a preliminary light-emitting element including a first electrode, a hole transport region disposed on the first electrode, an emission layer disposed on the hole transport region, and a first electron transport layer disposed on the emission layer, forming an electron injection layer on the first electron transport layer and the second electron transport layer, and forming a second electrode including a second-first electrode disposed on the second electron transport layer and a second-second electrode adjacent to the second-first electrode in a plan view by providing a metal mixture including a first metal and a second metal on the electron injection layer. The second-first electrode may include the first metal and the second-second electrode may include the first metal and the second metal, and a surface energy of a material included in the second electron transport layer is lower than a surface energy of the first metal and is higher than a surface energy of the second metal.

In an embodiment, the first metal may include Ag, and the second metal may include Mg.

In an embodiment, a light absorption rate of the second-first electrode may be lower than a light absorption rate of the second-second electrode.

In an embodiment, an area of the second electron transport layer in a plan view may be smaller than an area of the first electron transport layer in a plan view.

In an embodiment, the material included in the second electron transport layer may include at least one of 9-(2,3,4,5,6-pentadeuteriophenyl)-10-(4-naphthalen-1-ylphenyl)anthracene and 5,5′″-perfluorohexyl-2,2′:5′,2″:5″,2″-quaterthiophene.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view of an electronic apparatus according to an embodiment of the disclosure;

FIG. 1B is a perspective view of a curved electronic apparatus according to an embodiment of the disclosure;

FIG. 2 is a schematic cross-sectional view of a display device according to an embodiment of the disclosure;

FIG. 3 is an enlarged plan view illustrating a portion of a display device DD according to an embodiment;

FIG. 4 is a schematic cross-sectional view of the display device DD according to an embodiment.

FIG. 5 is an enlarged schematic cross-sectional view illustrating a portion of a display device according to an embodiment.

FIG. 6 is a flow chart showing a method of manufacturing a light-emitting element according to an embodiment of the disclosure; and

FIGS. 7, 8, 9, and 10 are schematic cross-sectional views showing some steps of the method of manufacturing a light-emitting element according to an embodiment.

### DETAILED DESCRIPTION OF THE EMBODIMENTS

Hereinafter, embodiments of the disclosure will be described with reference to the accompanying drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numerals and symbols refer to like elements. In addition, in the drawings, the thickness, the ratio, and the dimensions of elements are exaggerated for an effective description of technical contents.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the disclosure. The singular forms are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

It should be understood that the terms such as “include”, and “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, when an element is referred to as being “directly disposed,” another element or layer, there are no intervening layers, films, regions, plates, and the like present between portions such as layers, films, regions, and plates and other portions. For example, two layers or two members are “directly disposed” may mean that the two layers or two members are disposed without using an additional member therebetween.

Unless otherwise defined, all terms (including technical and scientific terms) used herein have the same meaning as commonly understood by one of ordinary skill in the art to which the disclosure pertains. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device according to an embodiment of the disclosure will be described with reference to the accompanying drawings.

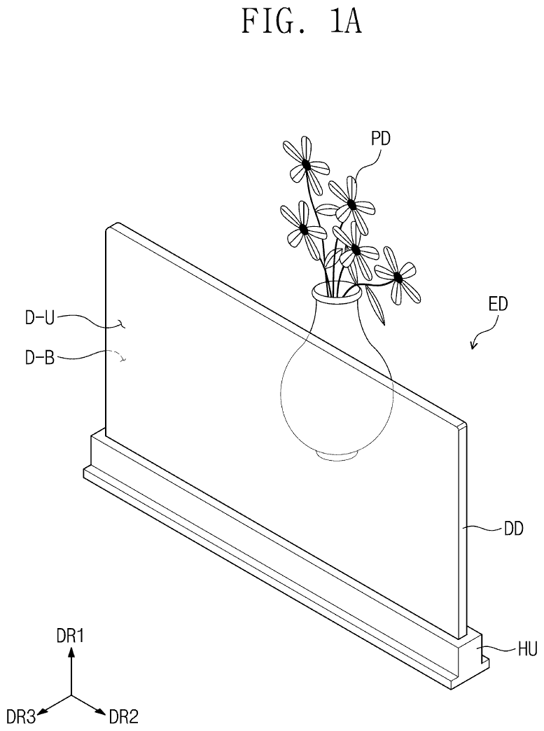

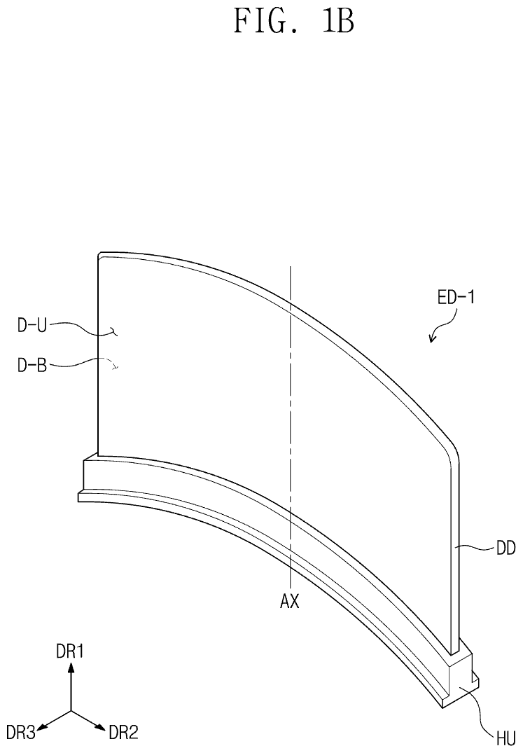

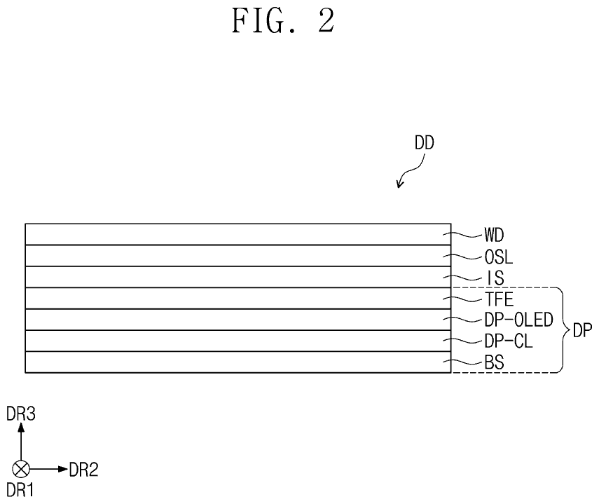

FIG. 1A is a perspective view of an electronic apparatus according to an embodiment of the disclosure. FIG. 1B is a perspective view of a curved electronic apparatus according to an embodiment of the disclosure. FIG. 2 is a schematic cross-sectional view of a display device according to an embodiment.

Electronic apparatuses ED and ED-1, illustrated in FIG. 1A and FIG. 1B may include a display device DD and a housing HU receiving at least a portion of the display device DD. For example, a portion of a lower part of the display device DD may be disposed in the housing HU.

Referring to FIG. 1A, the display device DD may display an image through a front surface D-U. A top surface of a member that is disposed on an upper most part of the display device DD may be defined as a front surface D-U of the display device DD. According to the disclosure, a top surface of a window illustrated in FIG. 2 may be defined as the front surface D-U of the display device DD.

In an embodiment, the front surface D-U may be parallel to a plane defined by a first direction DR1 and a second direction DR2. A normal direction of the front surface D-U, for example, a thickness direction of the display device DD may be indicated by a third direction. A front surface (or a top surface) and a rear surface (or a bottom surface) of each layer or unit, which will be described below, may be separated by the third direction DR3.

The display device DD according to an embodiment of the disclosure may be a transparent display device DD. The transparent display device DD may display information in a state where an object PD disposed on the rear surface D-B of the display device DD may be transparently projected onto the front surface D-U of the display device DD. Therefore, the user may view the object disposed behind the rear surface D-B of the display device DD from the front surface D-U of the display device DD. The information is not limited to an image, content, playback screen, application execution screen, web browser screen, graphic objects, and the like. A flower vase is illustrated in FIG. 1A, as an example of the object PD, but the object PD is not limited thereto as long as having specific shapes and being an object.

The housing HU may protect the display device DD from an external shock or invasion of foreign substances. The housing HU may be composed of a material such as a plastic, and a metal. However, the disclosure is not limited thereto as long as the materials are capable of protecting the display device DD from the external shock or invasion of foreign substances. In the electronic apparatus ED according to an embodiment, the housing HU may be omitted, and the display device DD may be rolled to be disposed inside the housing HU by an additional hinge member, and the housing thereof is not limited to any one embodiment.

Referring to FIG. 1B, the electronic apparatus ED-1 according to an embodiment may be curved along the second direction DR2 with respect to a virtual axis AX extending in the first direction DR1. Therefore, the display device DD may be curved with a curvature, and the housing HU may have a corresponding curvature. However, the disclosure is not limited thereto, and the axis may extend in the second direction DR2 or the display device may be curved with respect to multiple axes extending in different directions from each other.

The display device DD may be a rollable display panel, a foldable display panel, or a slidable display panel, and the whole display device DD may be disposed inside the housing HU in an operation mode. Therefore, the display device DD may include a curved display surface or a three-dimensional display surface. The three-dimensional display surface may include multiple display regions facing different directions.

Referring to FIG. 2, the display device DD according to an embodiment of the disclosure may include a display panel DP, an input sensor IS, an optical layer OSL, and a window WD. The display panel DP may include a base substrate BS, a circuit layer DP-CL disposed on the base substrate BS, a display element layer DP-OLED, and an encapsulation layer TFE. The display device DD may further include a functional layer such as an anti-reflection layer and a refractive index control layer.

The display panel DP may be a luminous-type display panel and may be one of a liquid crystal display panel, an electrophoretic display panel, a microelectromechanical system (MEMS) display panel, an electrowetting display panel, an organic light emitting display panel, an inorganic light emitting display panel, and a quantum-dot display panel, but the disclosure is not particularly limited thereto.

The base substrate BS may include a synthetic resin layer. A synthetic resin layer may include a thermosetting resin. For example, the synthetic resin layer may be a polyimide-based resin, and materials thereof are not particularly limited. The synthetic resin layer may include at least one of an acrylic resin, a methacrylic resin, polyisoprene, a viny-based resin, an epoxy-based resin, a urethane-based resin, a cellulose-based resin, a siloxane-based resin, a polyamide-based resin, and a perylene-based resin. In an embodiment, the base substrate BS may be a glass substrate, a metal substrate, an organic/inorganic composite material substrate, etc.

The circuit layer DP-CL includes multiple insulation layers and circuit elements. The insulation layers, which will be described below, may include an organic layer and/or an inorganic layer. The circuit layer DP-CL may include an insulation layer, a semiconductor layer, and a conductive layer formed through processes such as coating, and deposition. Thereafter, the insulation layer, the semiconductor layer, and the conductive layer may be selectively patterned through photolithography and etching processes. Through such processes, a semiconductor pattern, a conductive pattern, a signal line, and the like may be formed. The pattern disposed on the same layer may be formed through a same process.

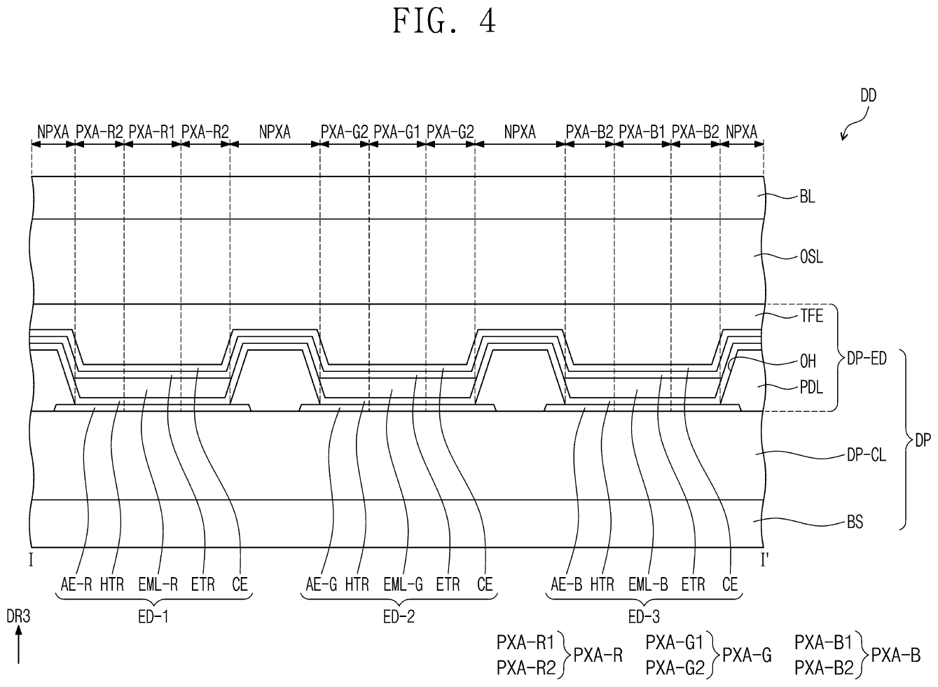

The circuit layer DP-CL may include a driving circuit or signal lines for driving a pixel PX. The display element layer DP-OLED may include light-emitting elements ED-1, ED-2, and ED-3 (FIG. 4) and a pixel definition layer PDL (FIG. 4), which are included in the pixel PX.

The encapsulation layer TFE may be disposed on the display element layer DP-OLED to protect the light-emitting elements ED-1, ED-2, and ED-3 (FIG. 4). The encapsulation layer TFE may include an inorganic layer and an organic layer disposed between the inorganic layers. The inorganic layer may protect the light-emitting elements ED-1, ED-2, and ED-3 from moisture and oxygen, and the organic layer may protect the light-emitting elements ED-1, ED-2, and ED-3 from foreign substances such as dust particles.

The input sensor IS may be directly disposed on the display panel DP. The input sensor IS may detect the user's input using a method of, for example, electromagnetic induction and/or capacitive sensing. The display panel DP and the input sensor IS may be formed through continuous processes. Herein, the term “directly disposed” may mean that no third component is disposed between the input sensor IS and the display panel DP. For example, no additional adhesive member may be disposed between the input sensor IS and the display panel DP.

The optical layer OSL may include optical control patterns which may change optical properties of source light generated in the light-emitting elements ED-1, ED-2, and ED-3 (FIG. 4). The optical layer OSL may reduce reflectance of external light incident from above the window WD. The optical control patterns may include quantum dots, and the optical layer OSL may include color filters selectively transmitting light that is transmitted to the optical control patterns. According to an embodiment, the optical layer OSL may be omitted.

The window WD may be disposed on the top of the display panel DP and may transmit an image that is provided from the display panel DP to the outside. The window WD may include a base layer and functional layers disposed on the base layer. The functional layers may include a protective layer, an anti-fingerprint layer, etc. The base layer of the window WD may be composed of glass, sapphires, plastics, etc.

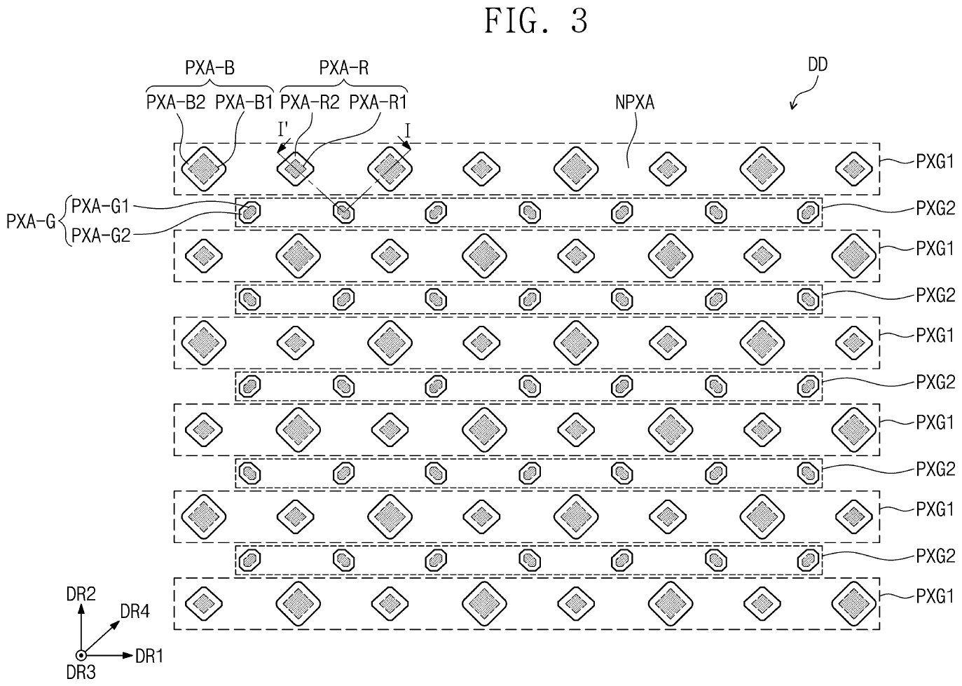

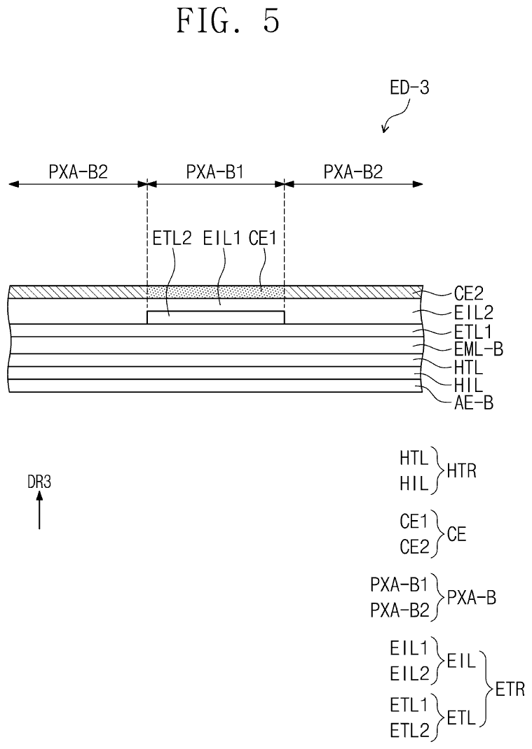

FIG. 3 is an enlarged plan view illustrating a portion of the display device DD according to an embodiment. FIG. 4 is a schematic cross-sectional view of the display device DD according to an embodiment. FIG. 4 illustrates a section taken along line I-I′ in FIG. 3. FIG. 5 is an enlarged schematic cross-sectional view illustrating a portion of the display device. FIG. 5 is an enlarged schematic cross-sectional view illustrating the second light-emitting element ED-2 of the display device DD illustrated in FIG. 4.

Referring to FIG. 3 and FIG. 4 together, the display device DD may include a non-emission region NPXA and emission regions PXA-B, PXA-G, and PXA-R. The emission regions PXA-B, PXA-G, and PXA-R may each be a region in which light generated in each of the light-emitting elements ED-1, ED-2, and ED-3 is emitted, respectively. The emission regions PXA-B, PXA-G, and PXA-R may be spaced apart from each other in a plan view.

The emission regions PXA-B, PXA-G, and PXA-R may be classified into multiple groups depending on the colors of light generated in the light-emitting elements ED-1, ED-2, and ED-3. In the display device DD according to an embodiment illustrated in FIG. 3 and FIG. 4, three emission regions PXA-B, PXA-G, and PXA-R, which emit blue, green, and red light, respectively, are illustrated. For example, the display device DD according to an embodiment may include a blue emission region PXA-B, a green emission region PXA-G, and a red emission region PXA-R which are distinguished from each other.

Referring to FIG. 3, the red emission region PXA-R may include a first red emission region PXA-R1 and a second red emission region PXA-R2. The first red emission region PXA-R1 may overlap the second red emission region PXA-R2 in a plan view. The second red emission region PXA-R2 may be adjacent to the first red emission region PXA-R1 on a plane. An area of the first red emission region PXA-R1 in a plan view may be smaller than an area of the red emission region PXA-R in a plan view. In FIG. 3, a shape of the first red emission region PXA-R1 is illustrated as a rhombus shape, but the shape of the first red emission region PXA-R1 is not limited thereto and may have various shapes including a circular or polygonal shape.

The green emission region PXA-G may include a first green emission region PXA-G1 and a second green emission region PXA-G2. The first green emission region PXA-G1 may overlap the second green emission region PXA-G2 in a plan view. The second green emission region PXA-G2 may be adjacent to the first green emission region PXA-G1 on a plane. An area of the first green emission region PXA-G1 in a plan view may be smaller than an area of the green emission region PXA-G in a plan view. In FIG. 3, a shape of the first green emission region PXA-G1 is illustrated as a rhombus shape, but the shape of the first green emission region PXA-G1 is not limited thereto and may have various shapes including a circular or polygonal shape.

The blue emission region PXA-B may include a first blue emission region PXA-B1 and a second blue emission region PXA-B2. The first blue emission region PXA-B1 may overlap the second blue emission region PXA-B2 in a plan view. The second blue emission region PXA-B2 may be adjacent to the first blue emission region PXA-B1 on a plane. An area of the first blue emission region PXA-B1 in a plan view may be smaller than an area of the blue emission region PXA-B in a plan view. In FIG. 3, a shape of the first blue emission region PXA-B1 is illustrated as a rhombus shape, but the shape of the first blue emission region PXA-B1 is not limited thereto and may have various shapes including a circular or polygonal shape.

In the display device DD according to an embodiment, the blue emission regions PXA-B and the red emission regions PXA-R may be alternatively arranged in the first direction DR1 and form a first group PXG1. The green emission regions PXA-G may be arranged in the first direction DR1 and form a second group PXG2. The first group PXG1 may be spaced apart from the second group PXG2 in the second direction DR2. The first groups PXG1s and the second groups PXG2s may be each provided in plurality. The first groups PXG1s and the second groups PXG2s may be alternatively arranged in the second direction DR2. One green emission region PXA-G may be disposed apart from one blue emission region PXA-B or one red emission region PXA-R in the fourth direction DR4. The fourth direction DR4 may be a direction between the first direction DR1 and the second direction DR2. An arrangement structure of the emission regions PXA-B, PXA-G, and PXA-R, illustrated in FIG. 3, may be referred to as the PenTile™ structure.

However, the disclosure is not limited thereto, the emission regions PXA-R, PXA-B, and PXA-G may have various polygonal shapes or circular shapes, and the arrangement structure of the emission regions is also not limited. For example, in an embodiment, the emission regions PXA-B, PXA-G, and PXA-R may be arranged in a stripe pattern, in which the blue emission region PXA-B, the green emission region PXA-G, and the red emission region PXA-R are sequentially arranged in turns in the first direction DR1, or a Diamond Pixel™ arrangement.

Referring to FIG. 4, the display device DD may include a display panel DP and an optical layer OSL disposed on the display panel DP. The optical layer OSL may be disposed on the display panel DP to control reflected light on the display panel DP due to the external light. The optical layer OSL may include, for example, a polarization layer or a color filter layer. In another embodiment, unlike what is illustrated in drawings, the optical layer OSL may be omitted in the display device DD.

A base substrate BL may be disposed on the optical layer OSL. The base substrate BL may be a member providing a base surface on which the optical layer OSL is disposed. The base substrate BL may be a glass substrate, a metal substrate, a plastic substrate, etc. However, the disclosure is not limited thereto, and the base substrate BL may be an inorganic layer, an organic layer, or a composite material layer. In another embodiment, the base substrate BL may be omitted.

The display device DD according to an embodiment may further include a charging layer (not illustrated). The charging layer (not illustrated) may be disposed between the display element layer DP-ED and the base substrate BL. The charging layer (not illustrated) may be an organic layer. The charging layer (not illustrated) may further include at least one of an acrylic resin, a silicon-based resin, and an epoxy-based resin.

The display panel DP may include, a base layer BS, a circuit layer DP-CL disposed on the base layer BS, and a display element layer DP-ED. The display element layer DP-ED may include a pixel definition layer PDL, light-emitting elements ED-1, ED-2, and ED-3 disposed between the pixel definition layers PDLs, and an encapsulation layer TFE disposed on the light-emitting elements ED-1, ED-2, and ED-3.

The base layer BS may be a member providing a base surface on which the display element layer DP-ED is disposed. The base layer BS may be a glass substrate, a metal substrate, a plastic substrate, etc. However, the disclosure is not limited thereto, and the base layer BS may be an inorganic layer, an organic layer, or a composite material layer.

In an embodiment, the circuit layer DP-CL may be disposed on the base layer BS, and the circuit layer DP-CL may include multiple transistors (not illustrated). The transistors (not illustrated) may each include a control electrode, an input electrode, and an output electrode. For example, the circuit layer DP-CL may include a switching transistor and a driving transistor for driving the light-emitting elements ED-1, ED-2, and ED-3 of the display element layer DP-ED.

The light-emitting elements ED-1, ED-2, and ED-3 may each have a structure of the third light-emitting element ED-3 described below with reference to FIG. 5. The first light-emitting element ED-1 may include a first electrode AE-R, a hole transport region HTR, an emission layer EML-R, an electron transport region ETR, and a second electrode CE. The second light-emitting element ED-2 may include a first electrode AE-G, a hole transport region HTR, an emission layer EML-G, an electron transport region ETR, and a second electrode CE. The third light-emitting element ED-3 may include a first electrode AE-B, a hole transport region HTR, an emission layer EML-B, an electron transport region ETR, and a second electrode CE.

In the light-emitting elements ED-1, ED-2, and ED-3 according to an embodiment, the first electrodes AE-R, AE-G, and AE-B may have conductivity. The first electrodes AE-R, AE-G, and AE-B may be made of a metal alloy or a conductive compound. The first electrodes AE-R, AE-G, and AE-B may be anode. The first electrodes AE-R, AE-G, and AE-B may be a pixel electrode.

In the light-emitting elements ED-1, ED-2, and ED-3 according to an embodiment, the first electrodes AE-R, AE-G, and AE-B may be reflective-type electrodes. However, the disclosure is not limited thereto. For example, the first electrodes AE-R, AE-G, and AE-B may be transmissive electrodes, or transflective electrodes, etc. In case that the first electrodes AE-R, AE-G, and AE-B are transflective electrodes or reflective electrodes, the first electrodes AE-R, AE-G, and AE-B may include Ag, Mg, Cu, Al, Pt, Pd, Au, Ni, Nd, Ir, Cr, Li, Ca, LiF/Ca, LiF/Al, Mo, Ti, or a compound or mixture thereof (for example, a mixture of Ag and Mg). In another embodiment, the first electrodes AE-R, AE-G, and AE-B may have a multi-layered structure including a reflective film or transflective film formed of the above-exemplified materials, or a transparent conductive film formed of indium tin oxide (ITO), indium zinc oxide (IZO), zinc oxide (ZnO), indium tin zinc oxide (ITZO), etc. For example, the first electrodes AE-R, AE-G, and AE-B may be a multi-layered metal film, or a stacked structure of a metal film of ITO/Ag/ITO.

The hole transport region HTR may be provided on the first electrodes AE-R, AE-G, and AE-B. The hole transport region HTR may include a hole injection layer HIL (FIG. 5), and a hole transport layer HTL (FIG. 5). In an embodiment, the hole transport region HTR may further include at least one of a hole buffer layer (not illustrated) and an electron blocking layer (not illustrated) in addition to the hole injection layer HIL (FIG. 5) and the hole transport layer HTL (FIG. 5). The hole buffer layer (not illustrated) may compensate for a resonance distance according to a wavelength of light emitted from the emission layers EML-R, EML-G, and EML-B to thereby increase luminous efficiency. Materials included in the hole transport layer HTR may be used as materials included in the hole buffer layer (not illustrated). The electron blocking layer (not illustrated) may serve to prevent electrons from being injected from the electron transport region ETR to the hole transport region HTR.

The hole transport region HTR may have a layer formed of a material, a layer formed of different materials, or a multi-layered structure having layers formed of different materials. For example, the hole transport region HTR may have a structure of single layer made of different materials, or a structure such as a hole injection layer HIL (FIG. 5)/hole transport layer HTL (FIG. 5), a hole injection layer HIL (FIG. 5)/hole transport layer HTL (FIG. 5)/hole buffer layer (not illustrated), a hole injection layer HIL (FIG. 5)/hole buffer layer (not illustrated), a hole transport layer HTL (FIG. 5)/hole buffer layer (not illustrated), or a hole injection layer HIL (FIG. 5)/hole transport layer HTL (FIG. 5)/electron blocking layer (not illustrated), which are sequentially stacked from the first electrodes AE-R, AE-G, and AE-B, but the disclosure is not limited thereto.

The hole transport region HTR may be formed using a method such as a vacuum deposition method, a spin coating method, a casting method, the Langmuir-Blodgett (LB) method, an inkjet printing method, a laser printing method, and a laser induced thermal imaging (LITI) method. The hole transport region HTR may have a thickness in a range of about 5 nm to about 1500 nm. For example, the hole transport region HTR may have a thickness in a range of about 10 nm to about 500 nm.

The emission layers EML-R, EML-G, and EML-B may include an organic emission material, or a quantum dot material. For example, the emission layers EML-R, EML-G, and EML-B may include an anthracene derivative, a pyrene derivative, a fluoranthene derivative, a chrysene derivative, a dihydrobenzanthracene derivative, or a triphenylene derivative as the organic emission material.

In the light-emitting element ED-D according to an embodiment, the emission layers EML-R, EML-G, and EML-B may include a host and a dopant. The emission layers EML-R, EML-G, and EML-B may include, as a dopant material, an organic fluorescent dopant material, an organic phosphorescent dopant material, a thermally activated delayed fluorescent dopant material, or a phosphorescent dopant material of an organic metal complex, etc.

The emission layers EML-R, EML-G, and EML-B may include at least one of bis[2-(diphenylphosphino)phenyl] ether oxide (DPEPO), 4,4′-bbis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA) and 1,3,5-tris(1-phenyl-1H-benzo[d]imidazole-2-yl)benzene (TPBi). However, the disclosure is not limited thereto, and the emission layers EML-R, EML-G, and EML-B may include, for example, at least one of tris(8-hydroxyquinolino)aluminum (Alq₃), 4,4′-bis(N-carbazolyl)-1,1′-biphenyl (CBP), poly(N-vinylcarbazole (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenyl cyclotrisiloxane (DPSiO₃), octaphenylcyclotetra siloxane (DPSiO₄), 2,8-bis(diphenylphosphoryl)dibenzofuran (PPF), etc.

In an embodiment, the emission layers EML-R, EML-G, and EML-B may include, as a dopant material, at least one of a styryl derivative (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), perylene and a derivative thereof (for example, 2,5,8,11-tetra-t-butylperylene (TBP)), pyrene and a derivative thereof (for example, 1,1-dipyrene, 1,4-dipyrenylbenzene, and 1,4-bis(N,N-diphenylamino)pyrene).

The emission layers EML-R, EML-G, and EML-B may include, for example, a metal complex containing iridium (Ir), platinum (Pt), osmium (Os), gold (Au), titanium (Ti), zirconium (Zr), hafnium (Hf), europium (Eu), terbium (Tb), or thulium (Tm) as a phosphorescent dopant material. For example, iridium(III) bis(4,6-difluorophenylpyridinato-N,C2′ (FIrpic), bis(2,4-difluorophenylpyridinato)-tetrakis(1-pyrazolyl) borate iridium (III) (Fir6), or platinum octaethyl porphyrin (PtOEP) may be used as a phosphorescent dopant material. However, the disclosure is not limited thereto.

The electron transport region ETR may be provided on the emission layers EML-R, EML-G, and EML-B. The electron transport region ETR may have a thickness in a range of, for example, about 20 nm to about 150 nm.

The electron transport region ETR may be formed by using a method such as a vacuum deposition method, a spin coating method, a casting method, the Langmuir-Blodgett (LB) method, an inkjet printing method, a laser printing method, and a laser induced thermal imaging (LITI) method.

The electron transport region ETR may include an anthracene-based compound. However, the disclosure is not limited thereto.

The electron transport region ETR may include a hole-blocking layer (not illustrated). The hole-blocking layer (not illustrated) may include, for example, at least one of 2,9-dimethyl-4,7-diphenyl-1,10-phenanthroline (BCP) and 4,7-diphenyl-1,10-phenanthroline (Bphen), but the disclosure is not limited thereto.

The second electrode CE may be a transflective electrode or transmissive electrode. In case that the second electrode CE is a transmissive electrode, the second electrode CE may be formed of a transparent metal oxide such as indium tin oxide (ITO), indium zinc oxide (IZO), zinc oxide (ZnO), and indium tin zinc oxide (ITZO).

In case that the second electrode CE is a transflective electrode or reflective electrode, the second electrode CE may include Ag, Mg, or a compound or mixture thereof (for example, AgMg). In an embodiment, the second electrode CE may have a multi-layered structure including a reflective film or transflective film made of the above-described materials and a transparent conductive film made of indium tin oxide (ITO), indium zinc oxide (IZO), zinc oxide (ZnO), indium tin zinc oxide (ITZO), etc. For example, the second electrode CE may include, the above-described metal materials, a combination of the above-described metal materials, an oxide of the above-described metal materials, etc.

Although not illustrated, the second electrode CE may be connected to an auxiliary electrode. If the second electrode CE is connected to the auxiliary electrode, a resistance of the second electrode CE may decrease.

FIG. 4 schematically illustrates that the emission layers EML-R, EML-G, and EML-B of the light-emitting elements ED-1, ED-2, and ED-3 are disposed in an opening OH defined in the pixel definition layer PDL, and the hole transport region HTR, the electron transport region ETR, and the second electrode CE are provided as common layers in the entire light-emitting elements ED-1, ED-2, and ED-3. However, the disclosure is not limited thereto, and unlike what is illustrated in FIG. 4, in another embodiment, the hole transport region HTR, and the electron transport region ETR may be provided inside the opening OH defined in the pixel definition layer PDL by a patterning operation. For example, in an embodiment, the hole transport region HTR, the emission regions EML-R, EML-G, and EML-B, the electron transport region ETR, and the like may be patterned by an inkjet printing method.

The encapsulation layer TFE may cover the light-emitting elements ED-1, ED-2, and ED-3. The encapsulation layer TFE may be disposed on the second electrode CE, and may fill the opening OH. The encapsulation layer TFE may seal the display element layer DP-ED. The encapsulation layer TFE may be a thin film-encapsulation layer. The encapsulation layer TFE may have a single layer or multiple layers stacked in the encapsulation layer TFE. The encapsulation layer TFE may include at least one insulation layer. The encapsulation layer TFE according to an embodiment may include at least one inorganic layer (hereinafter, referred to as an encapsulation inorganic layer). The encapsulation layer TFE according to an embodiment may include at least one organic layer (hereinafter, referred to as an encapsulation organic layer) and at least one encapsulation inorganic layer.

The encapsulation inorganic layer may protect the display element layer DP-ED from moisture/oxygen, and the encapsulation organic layer may protect the display element layer DP-ED from foreign substances such as dust particles. The encapsulation inorganic layer may include silicon nitride, silicon oxynitride, silicon oxide, titanium oxide, aluminum oxide, etc., but the disclosure is not particularly limited thereto. The encapsulation organic layer may include an acrylic compound, an epoxy-based compound, etc. The encapsulation organic layer may include a photopolymerizable organic material, but the disclosure is not particularly limited thereto.

The display device DD according to an embodiment may include a non-emission region NPXA and emission regions PXA-R, PXA-G, and PXA-B. The emission regions PXA-R, PXA-G, and PXA-B may each emit light generated in the light-emitting elements ED-1, ED-2, and ED-3, respectively. The emission regions PXA-R, PXA-G, and PXA-B may be spaced apart from each other in a plan view.

In the display device DD according to an embodiment, the light-emitting elements ED-1, ED-2, and ED-3 may emit light in different wavelength regions. For example, in an embodiment, the display device DD may include a first light-emitting element ED-1 emitting red light, a second light-emitting element ED-2 emitting green light, and a third light-emitting element ED-3 emitting blue light. For example, the red emission region PXA-R, the green emission region PXA-G, and the blue emission region PXA-B of the display device DD may correspond to the first light-emitting element ED-1, the second light-emitting element ED-2, and the third light-emitting element ED-3, respectively.

However, the disclosure is not limited thereto, and the first to third light-emitting elements ED-1, ED-2, and ED-3 may emit light with a same wavelength, or at least one may emit light in a different wavelength region. For example, the first to third light-emitting elements ED-1, ED-2, and ED-3 may all emit blue light.

Referring to FIG. 5, the hole transport region HTR may include a hole injection layer HIL, and a hole transport layer HTL.

The hole injection layer HIL may include, for example, a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris {N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPD), polyetherketone containing triphenylamine (TPAPEK), 4-isopropyl-4′-methyldiphenyliodonium[tetrakis(pentafluorophenyl)borate], dipyrazino[2,3-f:2′,3′-h] quinoxaline-2,3,6,7,10,11-hexacarbonitrile (HAT-CN), etc.

The hole transport layer HTL may further include a common material in the art. For example, the hole transport layer HTL may further include a carbazole-based derivative such as N-phenyl carbazole, and polyvinyl carbazole, a fluorene-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl)triphenylamine (TCTA), N,N′-di(naphthalene-1-yl)-N,N′-diphenyl-benzidine (NPD), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole injection layer HIL may have a thickness in a range of, for example, about 3 nm to about 100 nm, and the hole transport layer HTL may have a thickness in a range of about 3 nm to about 100 nm. For example, the electron blocking layer (not illustrated) may have a thickness in a range of about 1 nm to about 100 nm. In case that the thicknesses of the hole transport region HTR, the hole injection layer HIL, the hole transport layer HTL, and the electron-blocking layer (not illustrated) fall within the above-described ranges, a satisfactory level of hole transport characteristics may be achieved without a substantial increase in driving voltage.

The electron transport region ETR may include an electron transport layer ETL and an electron injection layer EIL. The electron transport layer ETL may be disposed on the emission layer EML-B. The electron transport layer ETL may be directly disposed on the emission layer EML-B. The electron transport layer ETL may include a first electron transport layer ETL1, and a second electron transport layer ETL2.

The first electron transport layer ETL1 may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole) (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), or a mixture thereof. The first electron transport layer ETL1 may have a thickness in a range of about 10 nm to about 100 nm. For example, the first electron transport layer ETL1 may have a thickness in a range of about 15 nm to about 50 nm. In case that the thickness of the first electron transport layer ETL1 falls within the above-described range, a satisfactory level of electron transport characteristics may be achieved without a substantial increase in driving voltage.

The second electron transport layer ETL2 may be disposed on the first electron transport layer ETL1. The second electron transport layer ETL2 may be directly disposed on the first electron transport layer ETL1. The second electron transport layer ETL2 may be disposed inside a first blue emission region PXA-B1. In another embodiment, the second electron transport layer ETL2 may be disposed inside a first red emission region PXA-R1 (FIG. 4), or a first green emission region PXA-G1 (FIG. 4). An area in a plan view of the second electron transport layer ETL2 may be smaller than an area in a plan view of the first electron transport layer ETL1. The second electron transport layer ETL2 may be patterned on a top surface of a portion of the first electron transport layer ETL1.

A surface energy of materials included in the second electron transport layer ETL2 may be in a range of about 0.642 J/m² to about 1.2 J/m². The surface energy used in this specification may mean a surface tension of a solid and may determine a behavior of a solid after contact with another material. For example, if a material having a low surface energy is provided on a surface of a solid having a high surface energy, it is difficult to be deposited on the sold due to a surface energy difference. The surface energy may be measured by using an optical tensiometer, and a contact angle obtained by providing each liquid drop of pure water, pure diiodomethane, and pure ethylene glycol may be applied to the Lewis Acid/Base model to calculate the surface energy. If a material having a smaller surface energy than the surface energy of the second electron transport layer ETL2 is provided on the second electron transport layer ETL2, the contact angle may increase due to a surface energy difference, and thus the deposition on the second transport layer ETL2 may be difficult. In case that a material having a surface energy similar to or higher than the surface energy of the second electron transport layer ETL2 is provided on the second electron transport layer ETL2, the contact angle may decrease, and thus the material may be readily deposited on the second electron transport layer ETL2.

The second electron transport layer ETL2 may include at least one of 9-(2,3,4,5,6-pentadeuteriophenyl)-10-(4-naphthalen-1-ylphenyl)anthracene and 5,5′″-perfluorohexyl-2,2′:5′,2″:5″,2″-quaterthiophene. For example, the second electron transport layer ETL2 may include 9-(2,3,4,5,6-pentadeuteriophenyl)-10-(4-naphthalen-1-ylphenyl)anthracene. The second electron transport layer ETL2 may have a thickness less than the thickness of the first electron transport layer ETL1.

The electron injection layer EIL may further include a halogenated metal such as LiF, NaCl, CsF, RbCl, RbI, a lanthanide metal such as Yb, a metal oxide such as LiO, BaO, lithium quinolate (LiQ), or the like, but the disclosure is not limited thereto. The electron injection layer EIL may be formed of a mixed material of the electron transport material, and an insulating organo metal salt. For example, the organo metal salt may include a metal benzoate, a metal acetoacetate, a metal acetylacetonate, or a metal stearate. The electron injection layer EIL may have a thickness in a range of about 0.1 nm to about 10 nm. For example, the electron injection layer EIL may have a thickness in a range of about 0.3 nm to about 9 nm. In case that the thickness of the electron injection layer falls within the above-described range, a satisfactory level of electron transport characteristics may be achieved without a substantial increase in driving voltage.

The electron injection layer EIL may include a first electron injection layer EIL1 and a second electron injection layer EIL2.

The first electron injection layer EIL1 may be disposed on the second electron transport layer ETL2. The first electron injection layer EIL1 may be directly disposed on the second electron transport layer ETL2. The first electron injection layer EIL1 may have a thickness less than a thickness of the second electron injection layer EIL2. If the thickness of the first electron injection layer EIL1 is less than the thickness of the second electron injection layer EIL2, a surface energy of materials contained in the second electron transport layer ETL2 may affect the material provided onto the first electron injection layer EIL1. Therefore, if the surface energy of the material provided on the first electron injection layer EIL1 is lower than the surface energy of the material contained in the second electron transport layer ETL2, it may be difficult for the material provided on the first electron injection layer EIL1 to be deposited on the first electron transport layer ETL1. Therefore, in a manufacturing process of the light-emitting element according to an embodiment of the disclosure, difficulty of the light-emitting element manufacturing process may be mitigated by using a difference between the surface energies without additional processes for patterning such as a mask process.

The second electron injection layer EIL2 may be disposed on the first electron transport layer ETL1. The second electron injection layer EIL2 may be directly disposed on the first electron transport layer ETL1. The second electron injection layer EIL2 may not overlap the second electron transport layer ETL2 in a plan view. The first electron injection layer EIL1 and the second electron injection layer EIL2 may have the integrated shape.

The second electrode CE may include a second-first electrode CE1, and a second-second electrode CE2.

The second-first electrode CE1 may be disposed on the second electron transport layer ETL2. The second-first electrode CE1 may be directly disposed on the first electron injection layer EIL1. The second-first electrode CE1 may not overlap the second-second electrode CE2 in a plan view. The second-first electrode CE1 may overlap in a plan view each of the first electron injection layer EIL1 and the second electron transport layer ETL2. An area of the second-first electrode CE1 and an area of the second electron transport layer ETL2 may be substantially the same in a plan view. The second-first electrode CE1 may include a first metal. The first metal may include Ag. The second-first electrode CE1 may include the first metal, and may not include a second metal, which will be described below. The second-first electrode CE1 may be formed of the first metal. The second-first electrode CE1 may be formed of Ag.

A light absorption rate of the second-first electrode CE1 may be lower than a light absorption rate of the second-second electrode CE2. The light absorption rate may be an indicator indicating how much light a specific material absorbs, expressed in percentage (%), which is calculated as a ratio of a first light energy projected onto the material and a second light energy after passing through the material. If the light absorption rate of the electrode of the display device is high, visibility may be reduced. As used herein, the light absorption rate may be measured for light in a wavelength in a range of about 430 nm to about 650 nm.

The second-second electrode CE2 may be adjacent to the second-first electrode CE1 in a plan view. The second-first electrode CE1 and the second-second electrode CE2 may be arranged parallel to each other in a direction intersecting the third direction DR3 which is a thickness direction.

The second-second electrode CE2 may be disposed on the second electron injection layer EIL2. The second-second electrode CE2 may be directly disposed on the second electron injection layer EIL2. The second-second electrode CE2 may not overlap, in a plan view, each of the second electron transport layer ETL2 and the first electron injection layer EIL1. The second-second electrode CE2 may include a second metal, in addition to the above-described first metal. The first metal may include Ag, and the second metal may include Mg. The surface energy of the first metal may be higher than the surface energy of the second metal. The surface energy of the materials contained in the second electron transport layer ETL2 may be lower than the surface energy of the first metal and higher than the surface energy of the second metal. The surface energy of the material contained in the second electron transport layer ETL2 may have a value between the surface energies of the first metal and the second metal. In a case where the surface energy of the material contained in the second electron transport layer ETL2 is lower than the surface energy of the first metal and higher than the surface energy of the second metal, in case that a composition including the first metal and the second metal is provided onto the second electron transport layer ETL2, the second metal having the relatively lower surface energy may not be deposited on the second electron transport layer ETL2, and thus the composition including the first metal may be selectively deposited on the second electron transport layer ETL2, which may mitigate the difficulty of the manufacturing process for the light-emitting element.

In FIG. 5, as an example, a schematic cross-section of the third light-emitting element ED-3 is illustrated, but the same descriptions may also be applied to the first light-emitting element ED-1, and the second light-emitting element ED-2.

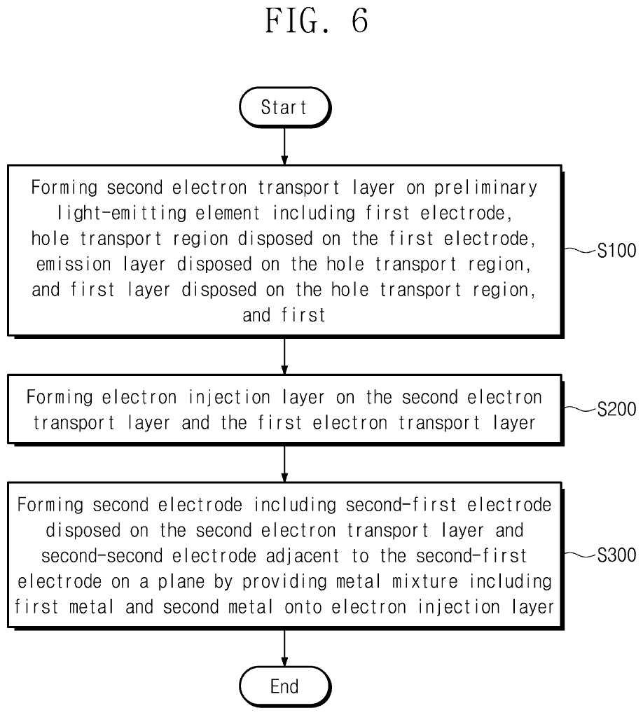

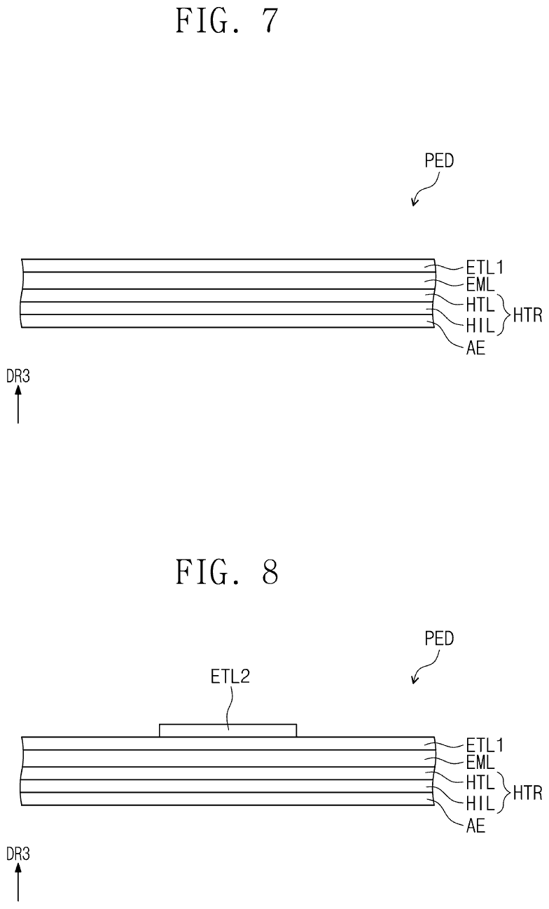

FIG. 6 is a flow chart of a method of manufacturing the light-emitting element according to an embodiment. FIG. 7 to FIG. 10 are each a schematic cross-sectional view showing some steps of the method of manufacturing the light-emitting element according to an embodiment. The descriptions of the duplicated components as the components described in FIG. 1 to FIG. 5 are omitted.

Referring to FIG. 6, the method of manufacturing the light-emitting element according to an embodiment may include forming a second electron transport layer (S100) on a preliminary light-emitting element that includes a first electrode, a hole transport layer disposed on the first electrode, an emission layer disposed on the hole transport region, and a first electron transport layer disposed on the emission layer, forming an electron injection layer (S200) on the second electron transport layer and the first electron transport layer, and forming a second electrode (S300) including a second-first electrode disposed on the second electron transport layer and a second-second electrode adjacent to the second-first electrode on a plane by providing a metal mixture including a first metal and a second metal onto the electron injection layer.

Referring to FIG. 7 and FIG. 8 together, in the forming of the second electron transport layer ETL2 on the preliminary light-emitting element PED, the second electron transport layer ETL2 may be formed using a method such as a vacuum deposition method, a spin coating method, a casting method, the Langmuir-Blodgett (LB) method, an inkjet printing method, a laser printing method, and a laser induced thermal imaging (LITI) method. For example, the second electron transport layer ETL2 may be formed using the inkjet printing method. The second electron transport layer ETL2 may be formed such that an area in a plan view of the second electron transport layer ETL2 is smaller than an area in a plan view of the first electron transport layer ETL1.

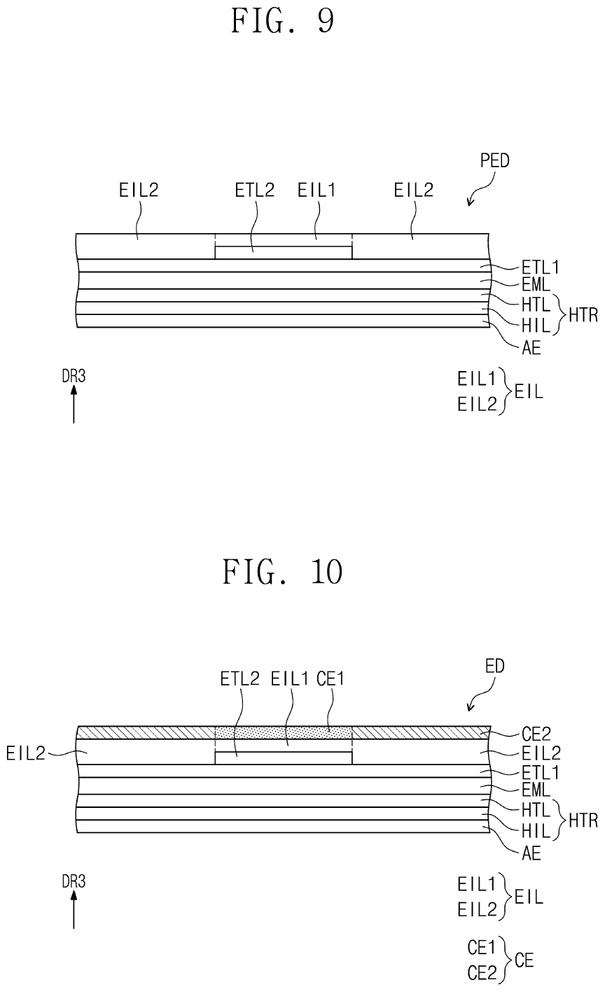

Referring to FIG. 9 and FIG. 10, in the forming of the electron injection layer EIL, the electron injection layer EIL may be formed using a method such as a vacuum deposition method, a spin coating method, a casting method, the Langmuir-Blodgett (LB) method, an inkjet printing method, a laser printing method, and a laser induced thermal imaging (LITI) method. For example, the electron injection layer EIL may be formed by the vacuum deposition method. The first electron injection layer EIL1 and the second electron injection layer EIL2 may be formed by the vacuum deposition method and may be formed to have an integrated shape.

In the forming of the second electrode CE, the second electrode CE may be deposited by physical vapor deposition (PVD), chemical vapor deposition (CVD), or atomic layer deposition (ALD). For example, the second electrode CE may be deposited by the atomic layer deposition method. In the forming of the second electrode CE, a composition including a first metal and a second metal may be provided on the electron injection layer EIL. The surface energy of the first metal may be higher than the surface energy of the second metal. The surface energy of the second electron transport layer ETL2 may be higher than the surface energy of the second metal and may be lower than the surface energy of the first metal. In case that the thickness of the first electron injection layer EIL1 is in a range of about 0.1 nm to about 0.5 nm, the first metal and the second metal disposed on the first electron injection EIL1 may be affected by the surface energy of the second electron transport layer ETL2. Since the surface energy of the second metal is lower than the surface energy of the second electron transport layer ETL2, the second metal may not be deposited on the second electron transport layer ETL2 but only on the second electron injection layer EIL2. Since the surface energy of the first metal is higher than the surface energy of the second electron transport layer ETL2, the first metal may be deposited on each of the second electron transport layer ETL2 and the second electron injection layer EIL2. Therefore, in the manufacturing process of the light-emitting element according to an embodiment of the disclosure, the second-first electrode CE1 and the second-second electrode CE2 may be formed separately even without additional processes for patterning such as a mask process, and thus difficulty of the manufacturing process of the light-emitting element including the second electron transport layer ETL2 may be mitigated. The first metal may include Ag, and the second metal may include Mg. Therefore, the second-first electrode CE1 may include Ag, and the second-second electrode CE2 may include Ag and Mg. The second-first electrode CE1 may be composed of Ag. Since Ag has a lower absorption rate for light in the wavelength in a range of about 430 nm and about 650 nm than an absorption rate of Mg for light in the same wavelength range, in case that the light-emitting element according to an embodiment of the disclosure including the second-first electrode CE1 composed of Ag is applied to a transparent display device, transparency of the light-emitting element may be improved.

The light-emitting element according to an embodiment may include an electrode including a material having a low light absorption rate for a region that requires low light absorption, using differences in surface energies, and thus transparency may be improved.

The display device according to an embodiment may include multiple light-emitting elements having improved transparency, thereby having improved transparency and resolution.

The method of manufacturing the light-emitting element according to an embodiment may use differences in surface energies, and thus may make a material having low surface energy and high light absorption rate among two materials having different surface energies, not be disposed in a region where requires low light absorption rate, thereby improving a manufacturing process difficulty.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light-emitting element comprising:
a first electrode;
a hole transport region disposed on the first electrode;
an emission layer disposed on the hole transport region;
an electron transport region disposed on the emission layer; and
a second electrode disposed on the electron transport region, wherein
the electron transport region includes an electron transport layer and an electron injection layer,
the electron transport layer includes a first electron transport layer and a second electron transport layer disposed on the first electron transport layer,
the second electrode includes a second-first electrode disposed on the second electron transport layer, and a second-second electrode adjacent to the second-first electrode in a plan view,
the second-first electrode includes a first metal,
the second-second electrode includes the first metal and a second metal, and
a surface energy of a material included in the second electron transport layer is lower than a surface energy of the first metal and higher than a surface energy of the second metal.

2. The light-emitting element of claim 1, wherein
the first metal comprises Ag, and
the second metal comprises Mg.

3. The light-emitting element of claim 1, wherein the surface energy of the first metal is higher than the surface energy of the second metal.

4. The light-emitting element of claim 1, wherein the surface energy of the materials included in the second electron transport layer is in a range of about 0.642 J/m² to about 0.2 J/m².

5. The light-emitting element of claim 1, wherein the electron injection layer comprises:
a first electron injection layer disposed on the second electron transport layer; and
a second electron injection layer disposed on the first electron transport layer and not overlapping the second electron transport layer in a plan view.

6. The light-emitting element of claim 5, wherein the first electron injection layer and the second electron injection layer are integral with each other.

7. The light-emitting element of claim 5, wherein the first electron injection layer is directly disposed on the second electron transport layer.

8. The light-emitting element of claim 5, wherein
the second-first electrode is directly disposed on the first electron injection layer, and
the second-second electrode is directly disposed on the second electron injection layer.

9. The light-emitting element of claim 5, wherein the first electron injection layer has a thickness smaller than a thickness of the second electron injection layer.

10. The light-emitting element of claim 1, wherein an area of the second electron transport layer and an area of the second-first electrode are substantially same in a plan view.

11. The light-emitting element of claim 1, wherein an area of the second electron transport layer in a plan view is smaller than an area of the first electron transport layer in a plan view.

12. The light-emitting element of claim 1, wherein the material included in the second electron transport layer comprises at least one of 9-(2,3,4,5,6-pentadeuteriophenyl)-10-(4-naphthalen-1-ylphenyl)anthracene and 5,5′″-perfluorohexyl-2,2′:5′,2″:5″,2′″-quaterthiophene.

13. The light-emitting element of claim 1, wherein the hole transport region comprises a hole injection layer disposed on the first electrode and a hole transport layer disposed on the hole injection layer.

14. A display device comprising:
a circuit layer disposed on a base layer; and
a display element layer disposed on the circuit layer and including a light-emitting element, wherein
the light-emitting element includes:
a first electrode;
a hole transport region disposed on the first electrode;
an emission layer disposed on the hole transport region;
an electron transport region disposed on the emission layer; and
a second electrode disposed on the electron transport region,
the electron transport region includes an electron transport layer and an electron injection layer,
the electron transport layer includes a first electron transport layer and a second electron transport layer disposed on the first electron transport layer,
the second electrode includes a second-first electrode disposed on the second electron transport layer and a second-second electrode adjacent to the second-first electrode in a plan view,
the second-first electrode includes a first metal,
the second-second electrode includes the first metal and a second metal, and
a surface energy of a material included in the second electron transport layer is lower than a surface energy of the first metal and higher than a surface energy of the second metal.

15. The display device of claim 14, wherein
the light-emitting element comprises a first light-emitting element that emits first light, a second light-emitting element that emits second light, and a third light-emitting element that emits third light, and
wavelengths of the first light, the second light, and the third light are different from each other.

16. A method of manufacturing a light-emitting element, comprising:
forming a second electron transport layer on a preliminary light-emitting element including a first electrode, a hole transport region disposed on the first electrode, an emission layer disposed on the hole transport region, and a first electron transport layer disposed on the emission layer;
forming an electron injection layer on the first electron transport layer and the second electron transport layer; and
forming a second electrode including a second-first electrode disposed on the second electron transport layer and a second-second electrode adjacent to the second-first electrode in a plan view by providing a metal mixture including a first metal and a second metal on the electron injection layer, wherein
the second-first electrode includes the first metal and the second-second electrode includes the first metal and the second metal, and
a surface energy of a material included in the second electron transport layer is lower than a surface energy of the first metal and is higher than a surface energy of the second metal.

17. The method of claim 16, wherein
the first metal includes Ag, and
the second metal includes Mg.

18. The method of claim 16, wherein a light absorption rate of the second-first electrode is lower than a light absorption rate of the second-second electrode.

19. The method of claim 16, wherein an area of the second electron transport layer in a plan view is smaller than an area of the first electron transport layer in a plan view.

20. The method of claim 16, wherein the material included in the second electron transport layer comprises at least one of 9-(2,3,4,5,6-pentadeuteriophenyl)-10-(4-naphthalen-1-ylphenyl)anthracene and 5,5′″-perfluorohexyl-2,2′:5′,2″:5″,2′″-quaterthiophene.
